(19) United States
(12) Patent Application Publication
(10) Pub. No.: US 2004/0262722 A1
(43) Pub. Date: Dec. 30, 2004

(54) Chip mounting method and mounted substrate manufacturing apparatus

(75) Inventor: Yoshinobu Sekiguchi, Tokyo (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/863,277

(22) Filed: Jun. 9, 2004

(30) Foreign Application Priority Data
Jun. 24, 2003 (JP) 2003-180271

(51) Int. Cl. H01L 23/48; H01L 21/44; H01L 21/48; H01L 21/301

(52) U.S. Cl. 257/676; 438/113; 438/114; 438/118; 438/464; 438/460

(57) ABSTRACT

A first adhesive member is adhered to a substrate formed with a circuit. After that, the substrate adhered with the first adhesive member is separated into a plurality of chips. Subsequently, an adhesion of a portion of the first adhesive member where desired chips are adhered is decreased, and the desired chips are selectively removed from the first adhesive member.

### FIELD OF THE INVENTION

The present invention relates to a chip mounting method and mounted substrate manufacturing apparatus.

### BACKGROUND OF THE INVENTION

A semiconductor device product is manufactured by, after a process of forming a circuit pattern on a wafer is ended, adhering the wafer on a malleable adhesive tape, separating the wafer into individual semiconductor chips by dicing, and adhering the semiconductor chips on desired substrates. In the step of adhering the semiconductor chips on the desired substrates, the adhesive tape to which the individual chips are adhered is spread to enlarge the gaps between the semiconductor chips, so that the semiconductor chips can be handled separately. Japanese Patent Laid-Open No. 2003-068832 discloses a technique of chucking semiconductor chips one by one with vacuum tweezers in this state, and mounting the semiconductor chips at desired positions of a mounted substrate with an adhesive material or the like.

In a device, for example, a semiconductor chip used in an RF tag, for which cost reduction is more demanded rather than increasing functions, the semiconductor chip size is decreased, and the yield of the semiconductor chips per wafer is increased, so that a low cost is achieved.

When, however, the semiconductor chip size is decreased, to mount an RF tag on an antenna substrate formed with an RF antenna, the distal end of the vacuum tweezers to be used must be thin. Then, the vacuum chucking area decreases, the vacuum chucking force decreases, and vacuum chucking of a semiconductor chip becomes difficult.

A decrease in volume is demanded particularly for a semiconductor device which is to be mounted in a portable device or the like. Hence, a stacked package is used in which semiconductor chips are stacked and mounted after they are polished thin. If the semiconductor chips are made extremely thin, when a semiconductor chip is to be chucked with the vacuum tweezers or to be bonded, a stress acts on the semiconductor chip, thus damaging the semiconductor chip.

### SUMMARY OF THE INVENTION

The present invention has been made in view of the above problems, and has as its object to mount, for example, a semiconductor chip effectively.

According to the first aspect of the present invention, there is provided a chip mounting method characterized by comprising steps of adhering a first adhesive member on a substrate formed with a circuit, separating the substrate adhered with the first adhesive member into a plurality of chips, and decreasing an adhesion of a portion of the first adhesive member where desired chips are adhered and selectively removing the desired chips from the first adhesive member.

According to the second aspect of the present invention, there is provided a chip mounting method characterized by comprising steps of separating a substrate formed with a circuit into two-dimensionally arrayed chips, arraying at least one column, as an array unit, of the two-dimensionally arrayed chips onto a first member one-dimensionally, and mounting at least one row, as an array unit, of a plurality of rows perpendicular to the one-dimensional chip column onto another substrate.

According to the third aspect of the present invention, there is provided a tag characterized by being mounted with a substrate fabricated using the above mounting method.

According to the fourth aspect of the present invention, there is provided a card characterized by being mounted with a substrate fabricated using the above mounting method.

According to the fifth aspect of the present invention, there is provided a mounted substrate manufacturing apparatus comprising a unit which decreases an adhesion of a portion of a first adhesive member adhered with a plurality of chips, desired ones of which are adhered on the portion, and a unit which selectively removes the desired chips from the first adhesive member.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIGS. 1A to 1D are views for explaining a mounted substrate manufacturing method according to the first preferred embodiment of the present invention;

FIGS. 2A to 2C are views for explaining the mounted substrate manufacturing method according to the first preferred embodiment of the present invention;

FIGS. 3A to 3C are views for explaining a mounted substrate manufacturing method according to the second preferred embodiment of the present invention;

FIGS. 4A to 4C are views for explaining the mounted substrate manufacturing method according to the second preferred embodiment of the present invention;

FIG. 5 is a conceptual view showing the arrangement of a manufacturing apparatus which manufactures a mounted substrate according to a preferred embodiment of the present invention; and

FIG. 6 is a conceptual view showing the arrangement of a manufacturing apparatus which manufactures a mounted substrate according to a preferred embodiment of the present invention.

### DETAILED DESCRIPTION OF THE PREFERRED EMBODIMENTS

The preferred embodiments of the present invention will be described with reference to the accompanying drawings.

### First Embodiment

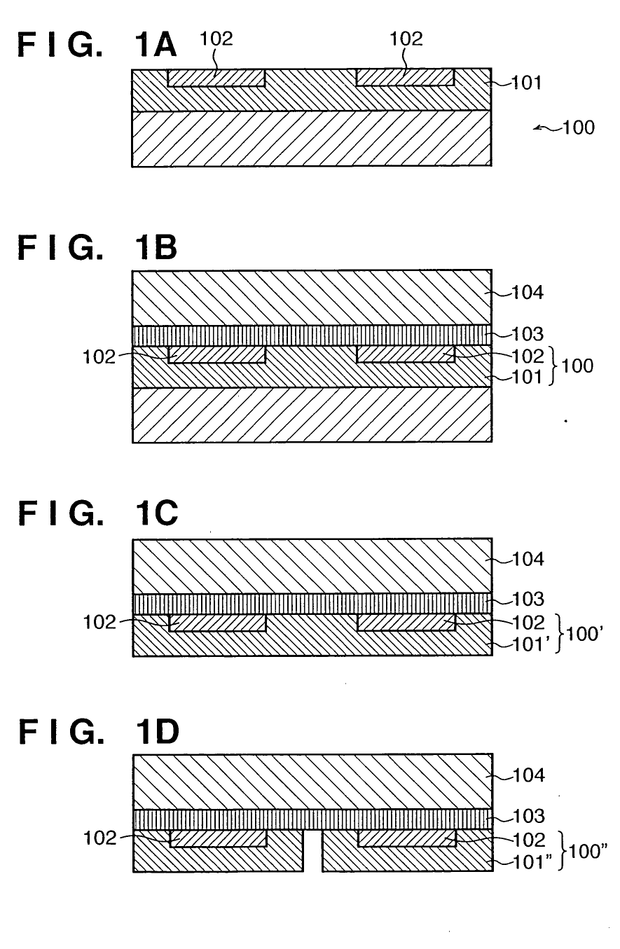

FIGS. 1A to 1D are views for explaining a mounted substrate manufacturing method according to the first preferred embodiment of the present invention.

In the step shown in FIG. 1A, a substrate 100 is prepared in which circuits 102 are formed on a semiconductor layer 101. To form the semiconductor layer 101, for example, an element semiconductor such as Si, Ge, or C may be used. Alternatively, an SiGe mixed crystal semiconductor, a two-element compound semiconductor such as GaAs, InAs, InP, GaP, GaN, AlN, or SiC, or a multi-element compound semiconductor, for example, a three-element or four-element compound semiconductor containing three or four elements as constituent elements, may be used.

In the step shown in FIG. 1B, a special adhesive tape 103 is adhered on circuit formation regions 102, and a handle substrate 104 is adhered on the special adhesive tape 103. The special adhesive tape 103 is made of a material whose adhesion decreases when it is heated to a predetermined temperature. An example of such a material includes an organic material which changes between a crystalline state and amorphous state at a predetermined temperature. When such a material is used, the adhesion can be largely changed upon a temperature change of about 10° C. between 30° C. and 60° C.

The adhesion can also be changed by ultraviolet ray irradiation to change bonding of a tacky material.

A special adhesive tape or adhesive whose adhesion decreases when it is heated to a predetermined temperature (or whose adhesion decreases when it is cooled to a predetermined temperature) is not particularly limited and, for example, Intelimer tape manufactured by Nitta Corporation can be employed.

The tacky tape which separates automatically when it is irradiated with ultraviolet rays is not particularly limited and, for example, SELFA (registered trademark) manufactured by Sekisui Chemical Co., Ltd. can be employed.

In the step shown in FIG. 1C, the lower surface of the substrate 100 is polished or etched to form a semiconductor layer 101′, to form a thinner substrate 100′. The method of forming a thin substrate is not limited to this. For example, a device layer transfer (DLT) technique may be used which separates the semiconductor layer 101 formed with the circuits 102 from the substrate 100 and transferring the semiconductor layer 101 onto another wafer, glass substrate, plastic substrate, or the like, to decrease the thicknesses of the semiconductor chips. When the thickness of the semiconductor chips is decreased by polishing or the like in accordance with a decrease in semiconductor chip size, advantages are obtained that handling of the semiconductor chips is facilitated and the volume of a semiconductor device on which the semiconductor chips are mounted can be decreased.

As such a device layer transfer technique, for example, a method shown in the following items (1) to (3) can be employed (for example, see Japanese Patent Laid-Open No. 05-218365).

(1) A single-crystal silicon substrate is anodized to form porous silicon on its surface. A single-crystal silicon thin film is epitaxially grown on porous silicon. Elements are formed in the epitaxial layer.

(2) The element-formed surface and a support substrate are adhered with a wax or the like, and the porous silicon portion is selectively etched.

(3) Subsequently, the element-formed epitaxial layer is adhered to a transparent insulating substrate containing SiO₂ as the main component with an adhesive. The wax is softened by overheating, and the support substrate and the element-formed epitaxial layer are separated from each other. Then, devices are fabricated in the epitaxial layer on SiO₂.

When the device layer transfer technique is employed, the lower surface of the substrate 100 need not be polished. Also, another semiconductor chip can be manufactured by using the separated substrate again.

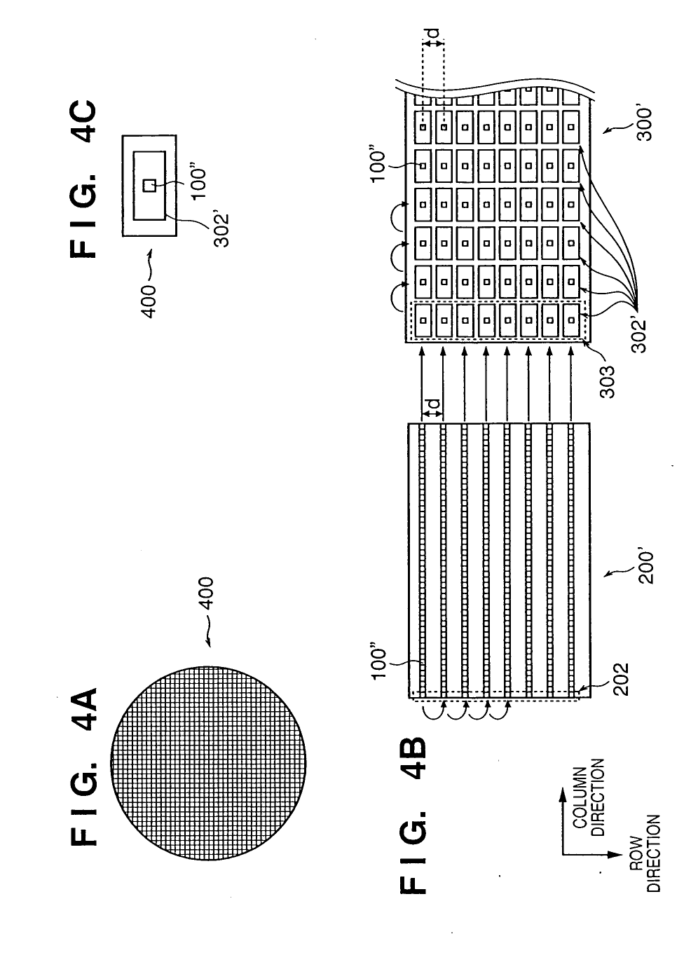

In the step shown in FIG. 1D, the substrate 100′ adhered on the special adhesive tape 103 is separated by dicing (called “scribing” as well) into a plurality of two-dimensionally arrayed chips 101″. The chips 101″ can be separated into several types of shapes in accordance with the preset conditions of a dicing device, and are typically separated to form substantial quadrangles (typically squares). Hence, the chips 101″ are typically arrayed in a matrix as shown in FIG. 4A.

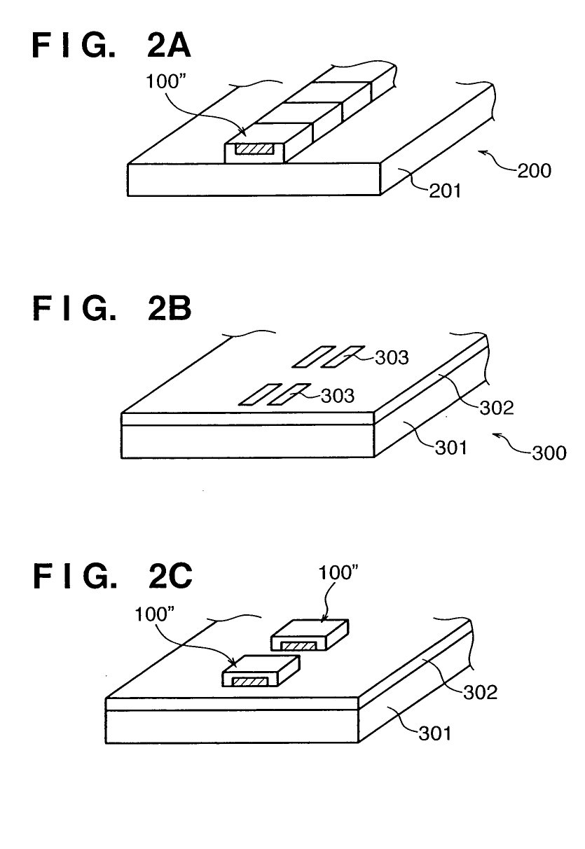

FIGS. 2A to 2C are views showing a method of mounting the chips 101″ manufactured by the above method onto another substrate.

In the step shown in FIG. 2A, of the plurality of chips 101″ formed in the step shown in FIG. 1D, the array of chips 101″ that are to be extracted is selectively removed onto a special adhesive tape 201. More specifically, first, that portion of the special adhesive tape 103 to which the array of the chips 101″ to be extracted is heated to decrease its adhesion. After that, the array of the chips 101″ on the heated portion is removed and is moved onto the special adhesive tape 201. As the method of heating the special adhesive tape 103, for example, a heater block may be urged against the array of the chips 101″ to be extracted, or the array of the chips 101″ may be irradiated with light that can be absorbed easily, thereby heating the special adhesive tape 103.

In the step shown in FIG. 2B, an antenna substrate 300 is prepared in which a wiring/RF antenna 302 is formed on a substrate 301. A conductive paste is applied to electrode pads 303 of the substrate 301 by drawing. As the antenna substrate 300, for example, a dielectric substrate can be used. To form the wiring/RF antenna 302 on the antenna substrate 300, any arbitrary material that can be used as a member which performs at least either radio wave transmission or reception can be employed and, for example, a metal material such as copper is preferably used.

In the step shown in FIG. 2C, the respective chips are removed from a chip array 100″ of FIG. 2A, and are face-down mounted on the electrode pads 303 of the antenna substrate 300 at the pitch of the wiring/RF antenna 302 of the antenna substrate 300.

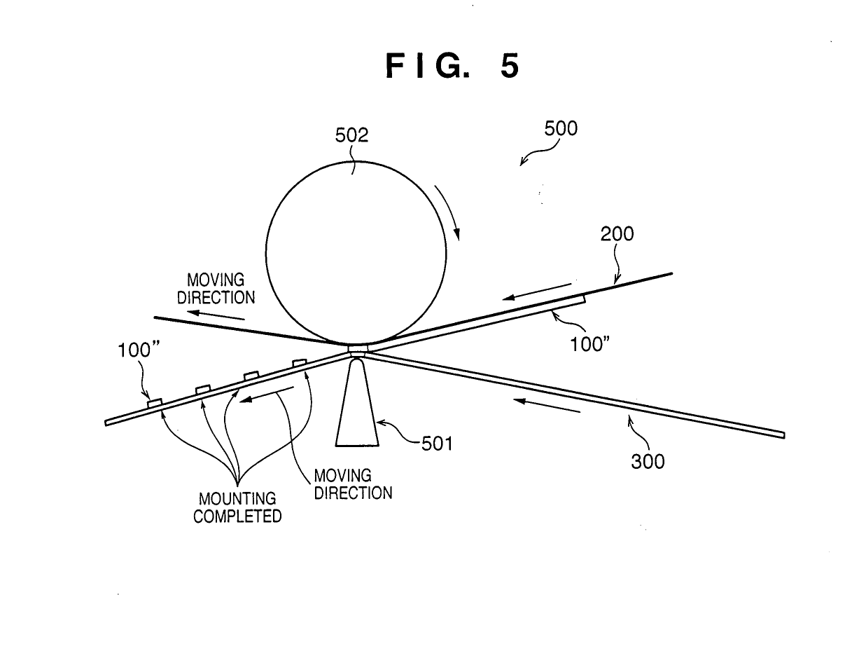

FIG. 5 is a conceptual view exemplifying the arrangement of a manufacturing apparatus 500 which manufactures a mounted substrate by using the method shown in FIG. 2C. As shown in FIG. 5, a special adhesive tape 200 on which the semiconductor chip array 100″ is formed is brought into surface contact with a rotary drum 502. The antenna substrate 300 printed with the wiring/RF antenna 302 is urged from its lower surface by a heater block 501, which has a distal end with substantially the same size as that of each chip 101″ and can move vertically. The antenna substrate 300 urged by the heater block 501 comes into tight contact with, among the chips 101″ adhered to the special adhesive tape 200, a chip 101″ located between the distal end of the heater block 501 and the rotary drum 502.

In this manner, with the lower surface of the antenna substrate 300 being urged by the heater block 501, when heat is applied to the antenna substrate 300 by the heater block 501, the chip 100″ in contact with the distal end of the heater block 501 is heated, and the adhesion of that portion of the special adhesive tape 200 where the heated chip 100″ is adhered decreases. The heated chip 100″ separates from the special adhesive tape 200, adheres to the conductive paste applied to the corresponding electrode pad 303 of the antenna substrate 300 by drawing, and is mounted on the antenna substrate 300.

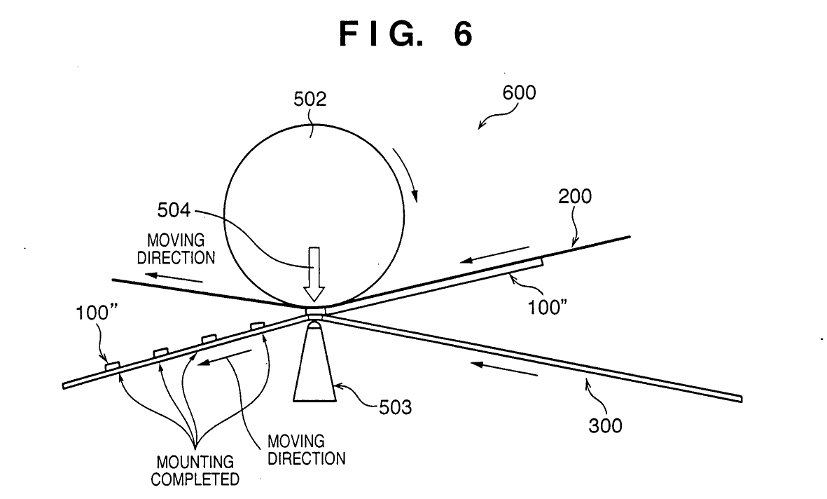

In place of heating the special adhesive tape 103 by using the heater block 501, the special adhesive tape 103 may be heated by light irradiation. FIG. 6 is a conceptual view showing the arrangement of a manufacturing apparatus 600 which manufactures a mounted substrate by using a light irradiation method. In FIG. 6, in place of the heater block 501, a contact bonding block 503 which can move vertically is used to urge the antenna substrate 300 from its lower surface. In this state, when a chip 100″ in contact with the distal end of the contact bonding block 503 is heated by irradiation with light from the upper surface of the special adhesive tape 200, the adhesion of that portion of the special adhesive tape 200 where the heated chip 100″ is adhered decreases, so that the semiconductor chip array 100″ can be mounted on the antenna substrate 300 easily. With the method of heating the special adhesive tape 103 by light irradiation, the adhesion surface of the chip 100″ can be heated within a short period of time, while surrounding semiconductor chips are not be heated easily.

As described above, according to this embodiment, semiconductor chips arrayed two-dimensionally on a special adhesive tape for dicing, the adhesion of which decreases by heating, can be heated for each array, and a desired chip array can be removed from the special adhesive tape. The removed chip array is moved to a special adhesive tape serving as another work base. A chip which is to be extracted is removed from the work base by decreasing its adhesion. After that, the chip can be mounted on an electrode pad of a tape-like antenna substrate printed with a wiring/RF antenna.

According to this embodiment, the adhesion of a chip or chip array to be extracted is selectively decreased, so that the specific chip or chip array can be handled. Thus, the specific chip or chip array can be mounted on the antenna substrate without handling the individual chip, enabling low-cost mounting. Different from a case wherein handling is performed by using vacuum tweezers, as handling is not influenced by the chip size, the chip size can be further decreased, and the cost can be decreased. Consequently, a downsized semiconductor chip and a semiconductor device, for example, an electronic tag, RF tag, or IC card, on which the semiconductor chip is mounted can be manufactured at a low cost.

### Second Embodiment

A substrate manufacturing method according to the second preferred embodiment of the present invention will be described. Roughly speaking, the substrate manufacturing method according to this embodiment is obtained by changing some of the steps in the mounted substrate manufacturing method according to the first embodiment shown in FIGS. 2A to 2C.

FIG. 4A shows a wafer 400 on which a plurality of chips formed by dicing are arrayed two-dimensionally by using the steps shown in FIGS. 1A to 1D.

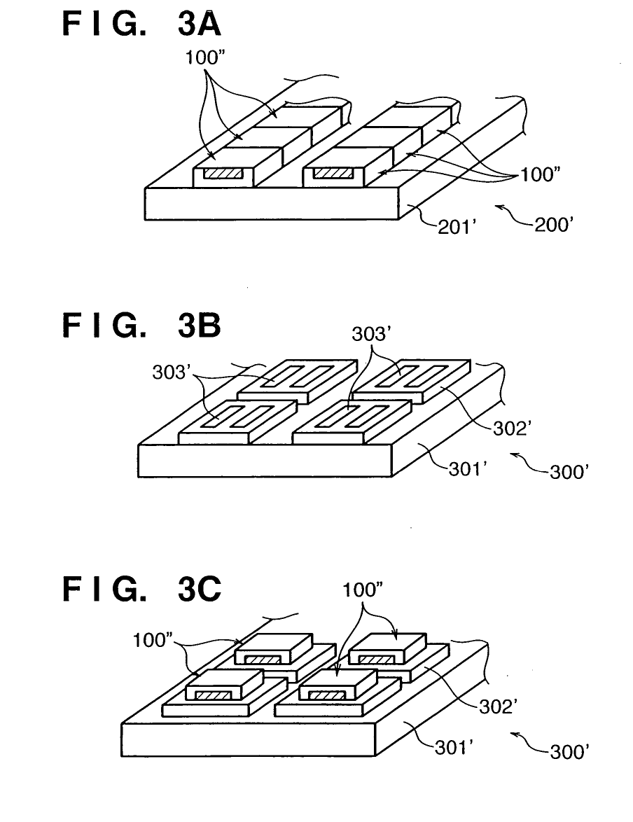

In the first step shown in FIG. 4B (left side), a plurality of chip arrays are arrayed one by one parallel to each other on a work sheet 200′ (special tacky tape). An interval d of these arrays is set to coincide with an array interval d of RF antennas 302′ on an antenna substrate 300′ which form a plurality of RF antenna arrays. More specifically, the special adhesive tape to which a chip array to be extracted is adhered is heated to decrease the adhesion of the special adhesive tape. Simultaneously, the work sheet 200′ is brought into tight contact with the chip array to be extracted. Thus, the chip arrays are transferred to the work sheet 200′ one by one. When this step is repeated, an embodiment in which a plurality of chip arrays are arrayed parallel to each other is realized. FIG. 3A is a partial perspective view of this embodiment. The chip arrays are desirably arrayed such that they have the same length as much as possible. A decrease in yield caused by partial drop-out is allowed for the benefit of cost reduction. Furthermore, as shown in FIG. 3B, in the same manner as in the first embodiment, the antenna substrate 300′ formed with the wiring/RF antennas 302′ is prepared in which a conductive paste is applied by drawing to electrode pads 303′ of a substrate 301′, as shown in FIG. 3B.

Subsequently, in the second step shown in FIG. 4B (right side), chips 100″ on the work sheet 200′ are urged for each row against the antenna substrate 300′ at mounting positions in the direction of the row which is a direction perpendicular to the chip columns, and are then heated to decrease the adhesion between the work sheet 200′ and the chips 100″. Then, the chips 100″ are face-down mounted on the antenna substrate 300′ from the work sheet 200′ for each row. For example, a chip array 202 on the first row of the work sheet 200′ is urged against at the mounting positions on an antenna array 303 on the first row of the antenna substrate 300′, and is heated, so that it is face-down mounted on the antenna array 303 for each row. With this step, a chip-mounted substrate as shown in FIG. 3C is realized.

After that, when necessary, the resultant structure may be heated to improve the electrical characteristics of the conductive paste, or molding or reinforcing may be performed or a protection film may be applied to protect the antenna substrate 300′. Then, the sheet-like antenna substrate 300′ is cut into individual substrates, thus completing an RF tag 400 shown in FIG. 4C.

As described above, according to this embodiment, a plurality of chip arrays can be mounted on an antenna substrate for each row. Thus, the degree of freedom of the mounting step increases, and the throughput can be improved.

A preferred embodiment of the present invention will be described.

According to this embodiment, an RF-ID chip is mounted on an RF antenna substrate. A semiconductor wafer 100, for which the process is ended and on the surface of which circuits 102 for the semiconductor chips for RF tags are formed, is prepared (corresponding to FIG. 1A). A base 104 was adhered to the circuit formation surface of the semiconductor wafer 100 through a special adhesive tape 103 whose adhesion decreases upon heating (corresponding to FIG. 1B). The lower surface of the semiconductor wafer 100 was polished to 50 μm (corresponding to FIG. 1C). The scribing positions were confirmed with ultraviolet rays from the polished surface on the lower side of the semiconductor wafer 100, and the semiconductor wafer 100 was separated into semiconductor chips 100′ by dicing (FIG. 1D).

Another special adhesive tape (work) 201 whose adhesion decreases when the temperature increases was urged against the polished surfaces of the semiconductor chips 100′, and a desired chip array was heated to decrease the adhesion. The whole array of the semiconductor chips 100′ were transferred from the handle substrate 104 to a work 201 (FIG. 2A). The temperature at which the adhesion of another special adhesive tape 201 decreases was set higher than that of the special adhesive tape 103 used for scribing. Thus, transfer of the whole array of the semiconductor chips 100′ was enabled.

The respective chips of the chip array transferred to the work 201 were sequentially urged against the mounting positions 303 of the sheet-like antenna substrate 300 on which a large number of RF antennas 302 were printed, and the chips were heated to decrease their adhesion. Hence, face-down mounting from the work 201 to the antenna substrate 300 was completed (FIG. 2C). In this case, as shown in FIGS. 5 and 6, the antenna substrate 300 printed with the RF antennas 302 and a special adhesive tape 200 on which the semiconductor array was arrayed were brought into tight contact with each other, and the chips were heated for each row from the lower surface of the antenna substrate 300. Thus, chip mounting was realized easily.

After that, when necessary, the resultant structure was heated to improve the electrical characteristics of the conductive paste, or molding or reinforcing was performed or a protection film was applied to protect the antenna substrate 300. Then, the sheet-like antenna substrate 300 was cut into individual substrates, thus completing an RF tag 400 as shown in FIG. 4C. In the above manner, a downsized semiconductor chip and an RF tag on which the downsized semiconductor chip was mounted can be manufactured at a low cost.

According to the present invention, for example, a semiconductor chip can be mounted effectively.

As many apparently widely different embodiments of the present invention can be made without departing from the spirit and scope thereof, it is to be understood that the invention is not limited to the specific embodiments thereof except as defined in the appended claims.

What is claimed is:

1. A chip mounting method comprising steps of:
adhering a first adhesive member on a substrate formed with a circuit;
separating the substrate adhered with the first adhesive member into a plurality of chips; and
decreasing an adhesion of a portion of the first adhesive member where desired chips are adhered and selectively removing the desired chips from the first adhesive member.

2. The method according to claim 1, wherein in the step of separating, the substrate formed with the circuit is separated into two-dimensionally arrayed chips.

3. The method according to claim 2, wherein in the step of removing, the adhesion of one or a plurality of arrays, as an array unit, of the two-dimensionally arrayed chips is decreased.

4. The method according to claim 1, wherein in the step of removing, the adhesion is decreased by heating the portion of the first adhesive member to a predetermined temperature.

5. The method according to claim 1, wherein in the step of removing, the adhesion is decreased by irradiating the portion of the first adhesive member with light.

6. The method according to claim 1, wherein the step of removing includes a step of bringing the desired chips into tight contact with a second adhesive member and transferring the desired chips from the first adhesive member to the second adhesive member.

7. The method according to claim 6, further comprising a step of mounting the chips on another substrate after the step of removing, wherein in the step of transferring the chips to the second adhesive member, the desired chips are arranged parallel to each other on the second adhesive member so as to match an interval with which the desired chips are to be mounted on another substrate.

8. The method according to claim 7, wherein in the step of mounting, the adhesion is decreased in at least one row, as an array unit, of a plurality of rows perpendicular to chip arrays arranged parallel to each other on the second adhesive member, and chips as the array unit are mounted at once at predetermined portions of another substrate.

9. The method according to claim 6, wherein when temperatures of the first and second adhesive members change to predetermined temperatures, the adhesion of the second adhesive member becomes larger than that of the first adhesive member.

10. The method according to claim 1, further including, before the step of adhering, a step of decreasing a thickness of a substrate to be formed with a circuit.

11. A chip mounting method comprising steps of:
separating a substrate formed with a circuit into two-dimensionally arrayed chips;
arraying at least one column, as an array unit, of the two-dimensionally arrayed chips onto a first member one-dimensionally; and
mounting at least one row, as an array unit, of a plurality of rows perpendicular to the one-dimensional chip column onto another substrate.

12. A tag characterized by being mounted with a substrate fabricated using the chip mounting method according to claim 1.

13. A card characterized by being mounted with a substrate fabricated using the chip mounting method according to claim 1.

14. A mounted substrate manufacturing apparatus comprising:
a unit which decreases an adhesion of a portion of a first adhesive member adhered with a plurality of chips, desired ones of which are adhered on the portion; and
a unit which selectively removes the desired chips from the first adhesive member.

15. The apparatus according to claim 14, wherein the unit which selectively removes brings the first adhesive member into tight contact with a second adhesive member, and transfers the desired chips from the first adhesive member to the second adhesive member.

16. The apparatus according to claim 14, wherein the unit which decreases the adhesion heats the portion of the first adhesive member.

17. The apparatus according to claim 14, wherein the unit which decreases the adhesion irradiates the portion of the first adhesive member with light.

18. The apparatus according to claim 15, wherein an adhesion generated when the second adhesive member is heated to a predetermined temperature is higher than that generated when the first adhesive member is heated to a predetermined temperature.
